(19) United States
(12) Patent Application Publication
(10) Pub. No.: US 2010/0237877 A1
(43) Pub. Date: Sep. 23, 2010

(54) SYSTEM OPEN-CIRCUIT TESTING METHOD

(75) Inventor: CHIH HSUEH HSU, KEELUNG (TW)

Correspondence Address: PAI PATENT & TRADEMARK LAW FIRM, 1001 FOURTH AVENUE, SUITE 3200, SEATTLE, WA, 98154, US

(73) Assignee: NIKO SEMICONDUCTOR CO., LTD., TAIPEI (TW)

(21) Appl. No.: 12/550,411

(22) Filed: Aug. 31, 2009

(30) Foreign Application Priority Data
Mar. 20, 2009 (TW) 098109232

(51) Int. Cl. G01R 31/02; H01H 31/12

(52) U.S. Cl. 324/551

(57) ABSTRACT

A system open testing method is provided. Firstly, a system to be tested having at least an ESD protection unit, a signal input pad, a first voltage level end, and a second voltage level end is provided, wherein the first voltage level end and the second voltage level end are utilized for accessing electric power, the ESD protection unit has one end coupled to the signal input pad and the other end coupled to the first voltage level end. Afterward, a diode is connected to the signal input pad, and the conducting direction of the diode is opposite to that of the interior diode in the ESD circuit. Thereafter, a testing signal is send through the diode to the system.

### BACKGROUND OF THE INVENTION

1. Field of the Invention

This invention relates to a system open-circuit testing method, and more particularly relates to a system open-circuit testing method for a system with an electrostatic-discharge (ESD) protection unit.

2. Description of Related Art

System open/short testing method, which is executed by inputting a testing signal to the system to be tested, is demanded to figure out whether there is any abnormal condition such as open-circuit or short circuit existed in this system. FIGS. 1a and 1b are schematic views showing two typical abnormal conditions. In FIG. 1a, the circuit connected between the system 10 and the power supply end VCC is opened, so that the electric power cannot be supplied to the system 10. In FIG. 1b, the circuit connected between the system 10 and the grounding end VSS is opened, so that the grounding voltage of the system would be floating.

Generally, in order to prevent system circuit from being damaged by electrostatic-discharge (ESD), there is usually an ESD protection unit implemented in the system for protection. FIG. 2 is a block diagram showing a typical electric system 10 with ESD protection units. As shown, the electric system 10 has an interior circuit 12 and two ESD protection units 14. The input signal is received from the signal input pad IN and executed by the interior circuit 12, and then an output signal is generated and outputted from the signal output pad OUT. The two ESD protection units 14 are connected between the signal input pad IN and the grounding end VSS as well as the signal output pad OUT and the grounding end VSS for protecting the interior circuit 12 of the electric system 10.

FIG. 3 is a block diagram showing another typical electric system 10 with ESD protection. As shown, the electric system 10 has an interior system 12 and four ESD protection units 14. The four ESD protection units 14 are connected between the signal input pad IN and the grounding end VSS, the signal output pad OUT and the grounding end VSS, the signal input pad IN and the power supply end VCC, as well as the signal output pad OUT and the power supply end VCC respectively.

However, referring to FIG. 2, as the circuit between the electric system 10 and the grounding end VSS is opened for example, the grounding voltage of the electric system 10 becomes floating. As a result, the voltage level of the grounding voltage would be varied attending with the input signal, which may influence the voltage level of the output signal or even damage the electric system 10.

### SUMMARY OF THE INVENTION

It is a main object of the present invention to provide a system open-circuit testing method, which is capable to eliminate the unwanted influence due to the ESD protection unit in the system to be tested.

The system open-circuit testing method provided according to an embodiment of the present invention comprises the steps as follow. Firstly, an electric system to be tested is provided. The electric system has at least one ESD protection unit, a signal input pad, a first voltage level end, and a second voltage level end, wherein the first voltage level end and the second voltage level end are utilized for accessing electric power, and the ESD protection unit has one end coupled to the signal input pad and another end coupled to the first voltage level end. Afterward, an additional diode is connected to the signal input pad. The conducting direction of the additional diode, which is electrically coupled to the ESD protection unit, is opposite to that of an interior diode of the ESD protection unit. Then, a testing signal is provided through the additional diode to the electric system.

In an embodiment of the present invention, the ESD protection unit has a metal-oxide-semiconductor (MOS) transistor.

In an embodiment of the present invention, the ESD protection unit has a silicon controlled rectifier (SCR) device.

### BRIEF DESCRIPTION OF THE DRAWINGS

The present invention will now be specified with reference to its preferred embodiment illustrated in the drawings, in which:

FIGS. 1a and 1b are schematic views showing typical abnormal architectures during system open-circuit testing;

FIG. 2 is a block diagram showing a typical electric system to be tested;

FIG. 3 is a block diagram showing another typical electric system to be tested;

FIG. 4 is a flow-chart showing a preferred embodiment of the system open-circuit testing method in accordance with the present invention;

FIG. 5 is a schematic view showing the architecture respective to the system opening circuit testing method described in FIG. 4;

FIG. 6a is a circuit diagram of the ESD protection unit in FIG. 5 according to a preferred embodiment of the present invention;

FIG. 6b is a circuit diagram of the ESD protection unit in FIG. 5 according to another preferred embodiment of the present invention;

FIG. 7 is a schematic view showing another preferred embodiment of the system open-circuit testing method according to the present invention;

FIGS. 8a and 8bare schematic views showing another preferred embodiment of the system open-circuit testing method according to the present invention;

FIG. 9a is a cross-section view showing a semiconductor structure corresponding to the electric circuit of FIG. 8a; and

FIG. 9b is a cross-section view showing a semiconductor structure corresponding to the electric circuit of FIG. 8b.

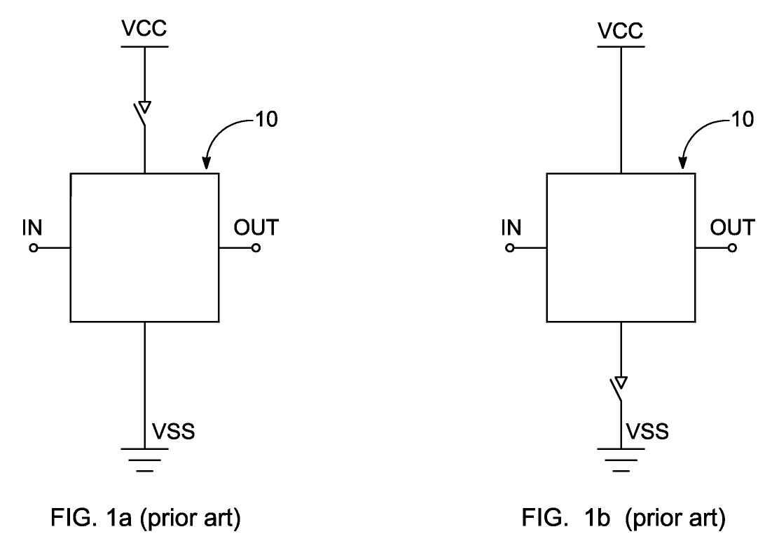

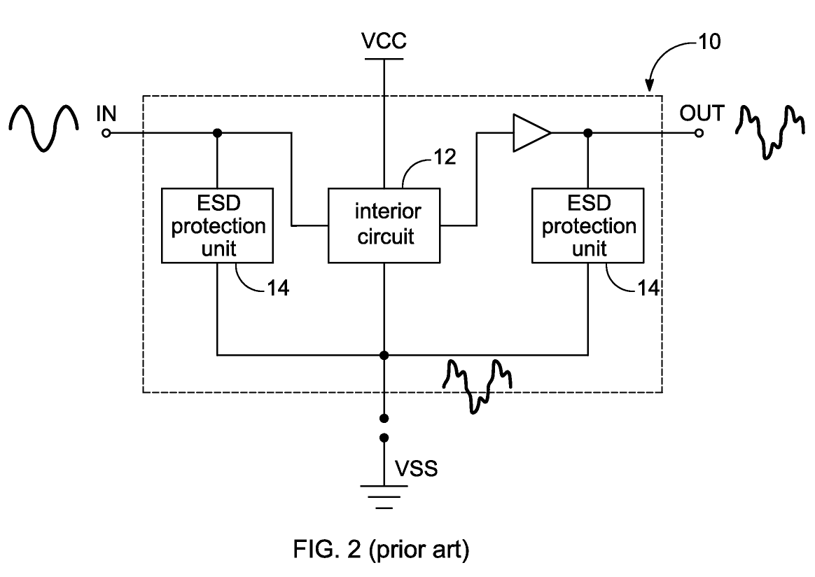

### DETAILED DESCRIPTION OF THE PREFERRED EMBODIMENTS

The feature of the present invention is to use a one-way conduction device, such as a diode, to prevent the grounding voltage level or the power supply voltage level of the electric system to be tested from being disturbed by the input signal to cause wrong-testing or even damage the electric system.

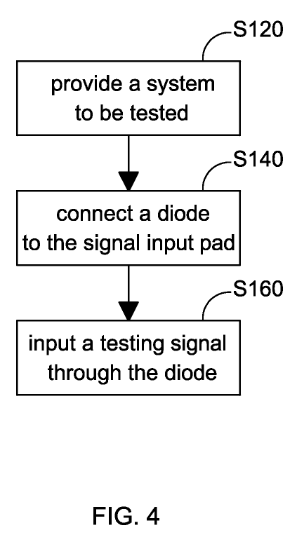

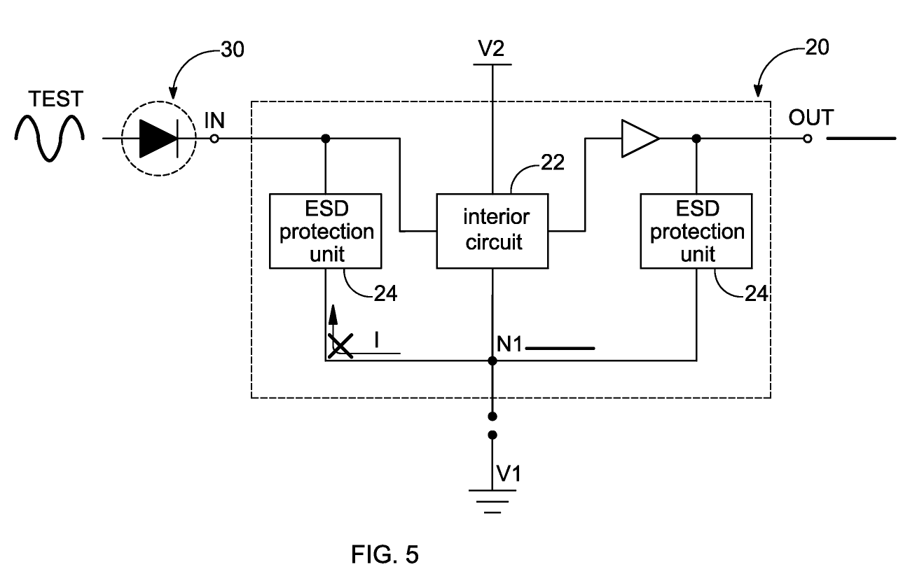

FIG. 4 is a flow-chart showing a preferred embodiment of the system open-circuit testing method in accordance with the preset invention, and FIG. 5 is a schematic view showing a preferred embodiment of a respective system architecture. Firstly, in step S120, an electric system 20 to be tested is provided. The electric system 20 has an interior circuit 22, at least one ESD protection unit 24, a signal input pad IN, a signal output pad OUT, a first voltage level end V1, and a second voltage level end V2. The voltage level of the second voltage level end V2 is higher than that of the first voltage level end V1. The first voltage level end V1 and the second voltage level end V2 are utilized for accessing electric power to run the electric system 20. For example, the first voltage level end V1 may be a grounding end VSS and the second voltage level end V2 may be a power supply voltage end VCC. The interior circuit 22 receives an input signal from the signal input pad IN and generates an output signal, which is outputted from the signal output pad OUT. For example, the interior circuit 22 may have a power MOS device with a gate electrode thereof coupled to the signal input pad IN and a drain electrode thereof coupled to the signal output pad OUT. In addition, the ESD protection unit 24 has one end coupled to the signal input pad IN and another end coupled to the first voltage level end V1.

Afterward, in step S140, an outside diode 30 is connected to the signal input pad IN. That is, the diode 30 is an additional device for the electric system to be tested. The outside diode 30 is electrically coupled to the ESD protection unit through the signal input pad IN, and the conducting direction of the outside diode 30 should be opposite to that of the interior diode of the ESD protection unit 24 to prevent the electric current I flowing from the ESD protection unit 24 toward the signal input pad IN from generated. Then, in step S160, a testing signal TEST is supplied to the electric system 20 through the outside diode 30 and the signal input pad IN.

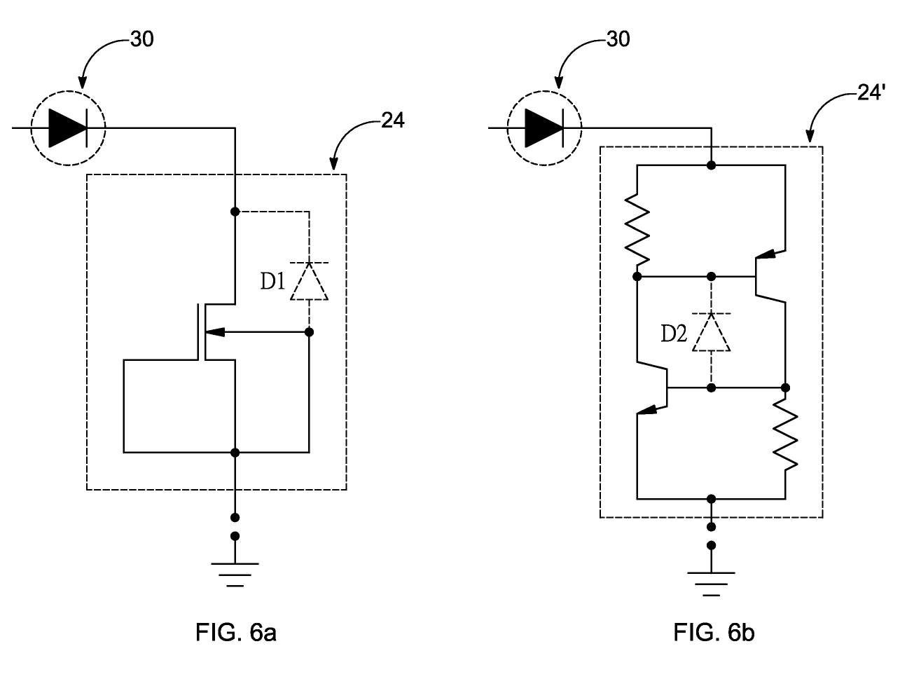

For a better understanding of the present invention, please refer to FIG. 6a, which shows an embodiment of the ESD protection unit 24 adopted in the present invention. As shown, the ESD protection unit 24 has a MOS transistor. It is understood that there is an interior diode D1, which is shown by the dashed line, in the MOS transistor. The conducting direction of the outside diode 30 connected to the signal input pad IN during the above mentioned step S140 is opposite to that of the interior diode D1 so as to prevent the grounding voltage level (the voltage level at node N1 in FIG. 5) of the electric system 20 from being disturbed by the signal inputted from the signal input pad IN. Referring to FIG. 6b, in another embodiment of the ESD protection unit 24′ of the present invention, the ESD protection unit 24′ has a SCR device. The SCR device also has an interior diode D2 shown by the dashed line. The conducting direction of the outside diode 30 connected to the signal input pad IN during the above mentioned step S140 is opposite to that of the interior diode D2 so as to prevent the grounding voltage level (the voltage level at node N1 in FIG. 5) of the electric system 20 from being disturbed by the signal inputted from the signal input pad IN.

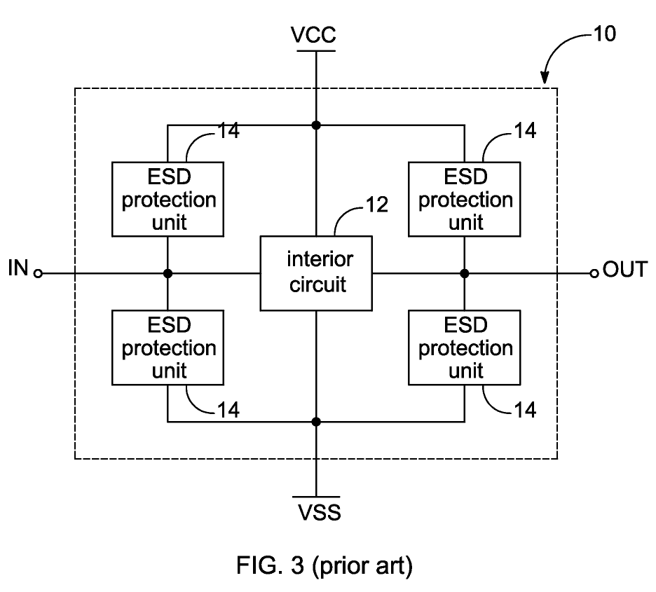

In the embodiment of FIG. 5, the ESD protection unit 24 has one end electrically connected to the signal input pad IN and another end electrically connected to the first voltage level end V1, which receives a voltage level lower than the second voltage level end V2. The outside diode 30 is utilized for protecting the electric system once the circuit corresponding to the first voltage level end V1 is opened. However, the scope of the present invention should not be so limited. Referring to FIG. 3, the idea of the present invention can be applied to the ESD protection unit connected between the signal input pad IN and power supply end VCC by connecting a diode to the signal input pad IN to prevent the voltage level of the power supply voltage of the electric system from being disturbed by the input signal.

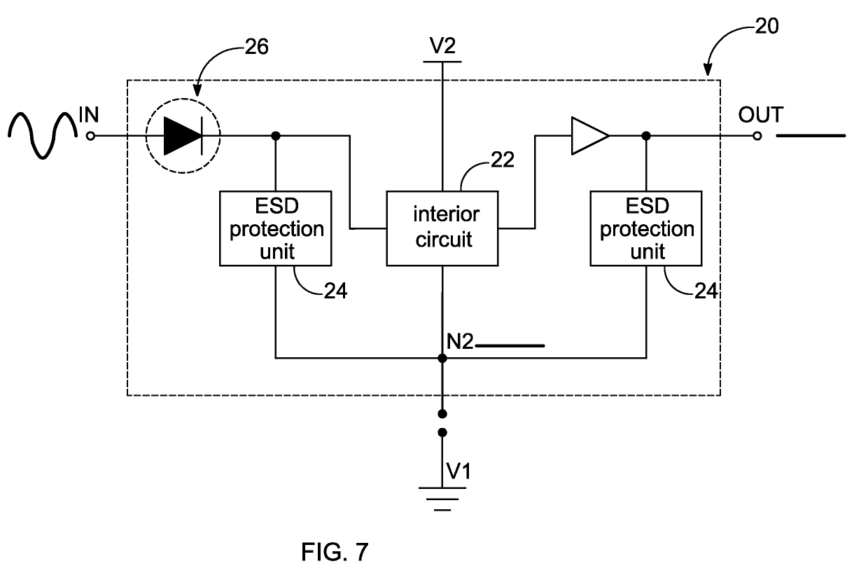

Moreover, in the embodiment of FIG. 5, the diode 30 is an additional device located outside the electric system 20 and the testing signal TEST is supplied to the signal input pad IN through the diode 30. However, the present invention is not so limited. Referring to FIG. 7, according to another embodiment of the present invention, the diode 26 is integrated in the electric system 20 and is connected between the signal input pad IN and the ESD protection unit 24.

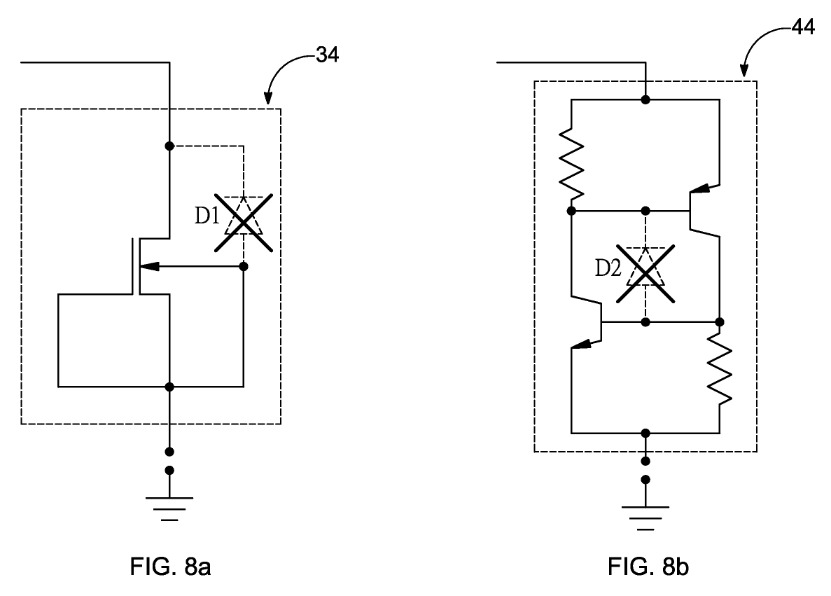

The above mentioned embodiments of FIG. 5 and FIG. 7 prevent the grounding voltage level (which is the voltage level at node N1 in FIG. 5 and node N2 in FIG. 7) of the circuit system from being disturbed due to the existence of the ESD protection unit 24 by serially connecting a diode 30 to the ESD protection unit 24. However, the preset invention is not so limited. Referring to FIGS. 8a and 8b, according to another embodiment of the present invention, the grounding voltage level of the electric system may be kept stable by removing the interior diode of the ESD protection unit 34,44.

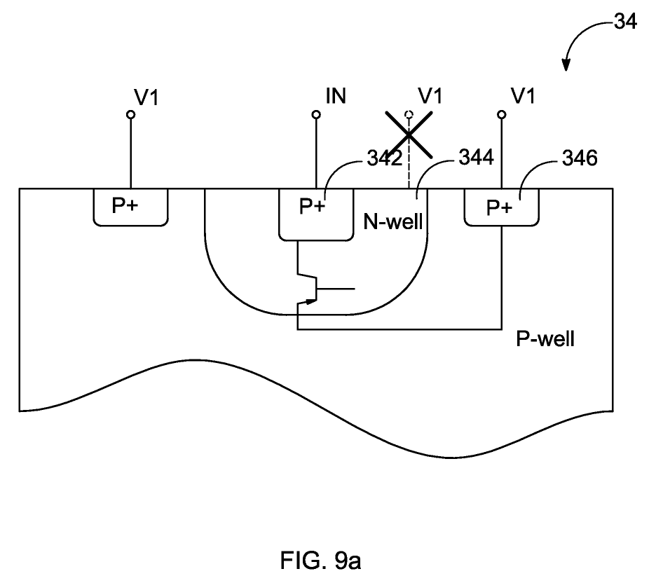

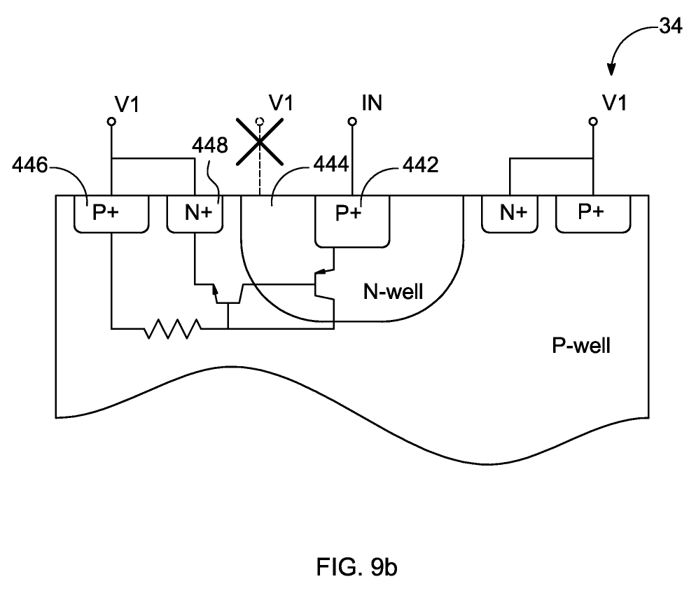

FIG. 9a is a cross-section view showing a semiconductor structure of the ESD protection unit 34 according to a preferred embodiment of the present invention. As shown, the ESD protection unit 34 has a parasitic BJT structure (PNP structure), wherein the P-type regions 342,346 can be regarded as the emitter and the collector of the BJT structure and the N-type region 344 can be regarded as the base of the BJT structure. The P-type regions 342,346 of the BJT structure are utilized for electrically connecting the signal input pad IN and the first voltage level end V1, respectively. The N-type region 344 located between the two P-type regions 342,346 is opened (floating) so as to eliminate the conducting path composed of the diode D1 inside the ESD protection unit 34.

FIG. 9b is a cross-section view showing a semiconductor structure of the ESD protection unit 44 according to a preferred embodiment of the present invention. As shown, the ESD protection unit 44 has a SCR device. The SCR device has a PNP structure and an NPN structure integrated with each other. That is, the SCR device also has a parasitic BJT structure. Wherein, the P-type regions 442,446 of the PNP structure are utilized for electrically connecting the signal input pad IN and the first voltage level end V1. One of the two N-type regions 448 of the NPN structure is utilized for electrically connecting the first voltage level end V1 and the other one N-type region 444, which is integrated with the N-type region of the PNP structure, is opened (floating) so as to eliminate the conducting path composed of the diode D2 inside the ESD protection unit 44.

As mentioned above, the system open-circuit testing method provided in the present invention is able to eliminate the unwanted influence comes from the ESD protection unit in the electric system so as to prevent the grounding voltage level of the circuit system from being disturbed by the input signal and prevent the electric system from being damaged by the abnormal input/output signal.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A system open-circuit testing method comprising the steps of:
providing an electric system to be tested, which has at least an ESD protection unit with an interior diode, an signal input pad, a first voltage level end and a second voltage level end, wherein the first voltage level end and the second voltage level end are utilized for accessing electric power, the ESD protection unit has one end coupled to the signal input pad and another end coupled to the first voltage level end;
connecting an additional diode to the signal input pad, and a conducting direction of the additional diode electrically connected to the ESD protection unit being opposite to that of the interior diode; and
providing a testing signal through the additional diode to the electric system to be tested.

2. The system open-circuit testing method of claim 1, wherein the ESD protection unit has a silicon controlled rectifier (SCR) device.

3. The system open-circuit testing method of claim 1, wherein the ESD protection unit has a metal-oxide-semiconductor (MOS) device.

4. The system open-circuit testing method of claim 1, wherein the electric system to be tested has a power MOS device with a gate electrode coupled to the signal input pad.

5. The system open-circuit testing method of claim 1, wherein the first voltage level end is a grounding end.

6. The system open-circuit testing method of claim 1, wherein the second voltage level end is a grounding end.

7. The system open-circuit testing method of claim 1, wherein the additional diode is removable.

8. A system open-circuit testing method comprising the steps of:
providing an electric system to be tested, which has at least an ESD protection unit with an interior diode, an signal input pad, a first voltage level end, and a second voltage level end, wherein the first voltage level end and the second voltage level end are utilized for accessing electric power, the ESD protection unit has one end coupled to the signal input pad and another end coupled to the first voltage level end;
assembling an additional diode on a circuit between the signal input pad and the ESD protection unit, wherein a conducting direction of the additional diode is opposite to that of the interior diode in the ESD protection unit; and
providing a testing signal to the electric system to be tested.

9. The system open-circuit testing method of claim 8, wherein the ESD protection unit has a silicon controlled rectifier (SCR) device.

10. The system open-circuit testing method of claim 8, wherein the ESD protection unit has a metal-oxide-semiconductor (MOS) device.

11. The system open-circuit testing method of claim 8, wherein the electric system to be tested has a power MOS device with a gate electrode coupled to the signal input pad.

12. The system open-circuit testing method of claim 8, wherein the first voltage level end is a grounding end.

13. The system open-circuit testing method of claim 8, wherein the second voltage level end is a grounding end.

14. A system open-circuit testing method comprising the steps of:
providing an electric system to be tested, which has at least an ESD protection unit, an signal input pad, a first voltage level end, and a second voltage level end, wherein the first voltage level end and the second voltage level end are utilized for providing electric power to the electric system, the ESD protection unit has at least a MOS device with a BJT structure which has a emitter and a collector connected to the signal input pad and the first voltage level end respectively;
having a base of the BJT structure of the MOS device opened to eliminate a conducting path formed by an interior diode of the MOS device; and
providing a testing signal to the electric system.

15. The system open-circuit testing method of claim 14, wherein the ESD protection unit has a SCR device.

16. The system open-circuit testing method of claim 14, wherein the electric system to be tested has a power MOS device with a gate electrode coupled to the signal input pad.

17. The system open-circuit testing method of claim 14, wherein the first voltage level end is a grounding end.

18. The system open-circuit testing method of claim 14, wherein the second voltage level end is a grounding end.
